(19) United States
(12) Patent Application Publication
(10) Pub. No.: US 2005/0201454 A1
(43) Pub. Date: Sep. 15, 2005

(54) System and method for automatically calibrating two-tap and multi-tap equalization for a communications link

(75) Inventors: Santanu Chaudhuri, Mountain View, CA (US); James McCall, Beaverton, OR (US); Konika Ganguly, Portland, OR (US); Michael Gutzmann, Forest Grove, OR (US); Sanjay Dabral, Palo Alto, CA (US); Ken Drottar, Portland, OR (US); Alok Tripathi, Beaverton, OR (US); Kersi Vakil, Olympia, WA (US)

Correspondence Address: FLESHNER & KIM, LLP, P.O. BOX 221200, CHANTILLY, VA, 20153, US

(73) Assignee: INTEL CORPORATION

(21) Appl. No.: 10/798,557

(22) Filed: Mar. 12, 2004

(51) Int. Cl. H03K 5/159

(52) U.S. Cl. 375/229

(57) ABSTRACT

A method to calibrate an equalizer for communicating signals over a data link between a transmitter and receiver includes measuring loss in the link and automatically determining a multi-tap equalization setting for the transmitter based on the measured loss. The multi-tap equalization setting may be determined using a look-up table, which stores a plurality of equalization settings for a respective number of link loss values. Once the equalization setting matching the measured link loss is found in the table, the equalizer can be optimally set to reduce or eliminate intersymbol and other types of interference.

### FIELD

The invention generally relates in one or more of its embodiments to signal processing techniques, and more particularly to a system and method for controlling equalization in a communications system.

### BACKGROUND OF THE INVENTION

Communication links are susceptible to noise and other influences which degrade signal quality at the receiver. Various techniques have been used to improve link performance. In mobile communication systems, one technique known as equalization compensates for inter-symbol interference (ISI) caused by the transmission medium in band-limited (frequency selective) time dispersive channels. ISI occurs when the modulation bandwidth exceeds the coherence bandwidth of the radio channel. This results in distorting the transmitted signal, causing bit errors at the receiver.

Equalization is a processing operation which minimizes ISI. As long as margins allow, transmitter-based equalization is a simpler and preferred process (compared to receiver-based equalization) in terms of circuit complexity and power dissipation. The process involves compensating for the average range of expected channel amplitude and delay characteristics. Because of the inherent properties of mobile channels, equalizers must track the time varying characteristics of the channel and therefore are said to be adaptive in nature.

Adaptive equalization is performed in multiple modes. During a training mode, a known fixed-length training sequence is sent by the transmitter so that the receiver equalizer may average to a proper setting. The training sequence is typically a pseudorandom binary signal or a fixed, prescribed bit pattern.

Immediately following the training sequence, the user data (which may or may not include coding bits) is sent and the equalizer at the receiver utilizes a recursive algorithm to evaluate the channel and estimate filter coefficients to compensate for the channel. The training sequence is designed to permit the equalizer to acquire the proper filter coefficients under the worst possible channel conditions, so that when the training sequence is finished the filter coefficients are near optimal values for reception of user data. As the user data is received, the adaptive algorithm of the equalizer tracks the changing channel conditions. The equalizer, thus, continually changes its filter characteristics over time to reduce ISI and thus improve the overall quality of data reception.

Many equalizers use fixed taps (PCI Express, Memory Interface, etc.) or component strapped values (XAUI). PCI Express is a serial I/O technology that is expected to be featured in PC's across all market segments in the near future. XAUI is another serial I/O interface which is commonly used for 10 Gbps optical Ethernet applications. In existing systems, both equalizer topologies are fixed at design time and cannot thereafter be adjusted. This is disadvantageous for a number of reasons. For example, the number of taps and filter-coefficient settings for one medium or channel may not be optimal for or may not even work for another channel. To overcome these inconsistencies, users of existing systems would manually vary certain parameters of the filter to make the link work for different channels, taking into consideration bit-rate as well as other variables. This not only proved to be time inefficient but also undermined system flexibility and adaptability.

### BRIEF DESCRIPTION OF THE DRAWINGS

FIG. 1 is a diagram showing a communication system in accordance with one embodiment of the present invention.

FIG. 2(a) is a diagram showing a two-tap equalizer that may be included in the system of FIG. 1, and FIG. 2(b) shows a five-tap equalizer that may be included in the system of FIG. 1.

FIG. 3 is a diagram showing an example of a lone pulse that may be output from an equalizer included in the transmitter of FIG. 1.

FIG. 4 is a diagram showing blocks included in a method that may be used to set equalization coefficients in the system of FIG. 1.

FIG. 5 is a diagram showing a handshaking procedure and loop-back communications that may be performed between the transmitter and receiver of FIG. 1 during equalization setting.

FIG. 6 is a diagram showing how voltage offset may be determined by the receiver to enable link loss to be determined.

FIG. 7 shows a DC pattern signal that may be used to derive link loss information.

FIG. 8 is a flow diagram showing blocks included in determining link loss in accordance with a preferred embodiment of the system and method of the present invention.

FIG. 9 is a diagram which conceptually shows how two equalization coefficients may be related to link loss computed in accordance with one or more embodiments of the present invention.

FIGS. 10(a) and 10(b) are graphs showing a relationship between multi-tap coefficients and link losst that may be used in accordance with one or more embodiments of the present invention.

FIG. 11 is a look-up table of multi-tap equalization coefficients that may be computed in advanced for a range of link loss values and used for automatically setting a transmitter equalizer in accordance with one or more embodiments of the system and method of the present invention.

FIG. 12 is a diagram of a processing system in accordance with an embodiment of the present invention.

### DESCRIPTION OF THE PREFERRED EMBODIMENTS

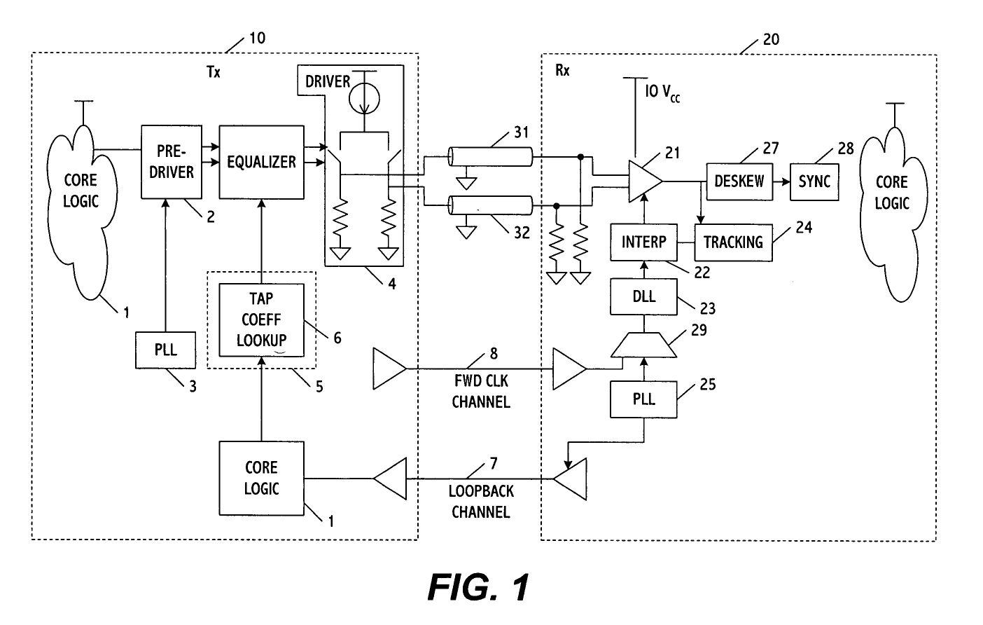

FIG. 1 shows a communications system which includes a transmitter 10 and a receiver 20 connected by one or more serial links 30. The transmitter includes core logic 1, a pre-driver 2, a phase-locked loop 3, a driver 4, and an equalizer 5. The core logic generates a baseband signal containing voice, data or other information to be transmitted. The pre-driver modulates the baseband signal on a carrier frequency generated by the phase-locked loop. The modulation preferably comports with one of a variety of spread-spectrum techniques including but not limited to CDMA. The driver performs switching operations for controlling the transmission of the modulated signal along one or more of the serial links. For illustrative purposes two serial links 31 and 32 are shown, however more links may be included. The links may be lossy interconnects, which may reside in a board connection without connectors or in other configurations such as but not limited to a two board-one connector configuration and a three board-two connector configuration.

The equalizer includes a memory 6 which stores a tap coefficient lookup table which is described in greater detail below. Preferably, the core logic that receives data from a loopback channel 7 between the transmitter and receiver also passes that data to the block that computes the coefficients output from the lookup table. A forward clock channel 8 is also included between the transmitter and receiver for reasons that will become apparent below. The forward clock and loopback channels may have the same architecture as that used for the general data channels 31 and 32. The forward clock channel may not require equalization (e.g., it may send only binary bit patterns 101010 . . . ). The loopback channel may be another data channel used to send data at low frequency back to the original transmitter bit. Also, while the equalizer is shown within the transmitter, the equalizer may also be placed outside the transmitter.

The receiver includes a demodulator and de-skew circuit. In the demodulator, data is received by a sampling amplifier 21 at the input and demodulated using sampling clock signals generated by an interpolator 22. The interpolator receives the clock signals from a delay locked loop (DLL) 23. The interpolator is controlled using a tracking loop 24, which keeps on tracking the relative phase of the data with respect to a clock output from a phase-locked loop 25. The de-skew circuit 27 and sync circuit 28 synchronizes the data received from all the bits of the port together. Also, a multiplexer 29 may be included for selecting the clock signals to be input into the delay-locked loop. The de-skew and sync blocks are considered optional since the equalization coefficients may be adjusted on a per-lane basis as will be described in greater detail.

The transmitter and receiver may receive the same reference clock for driving their respective phase-locked loop circuits. Also, a forward clock channel may be established between the transmitter and receiver. The adaptive equalizer reduces ISI interference in the received signal for improving signal quality.

In accordance with at least one embodiment of the present invention, a response/feedback channel may be used for each channel being calibrated. To reduce overhead of extra channels, tap coefficients and/or other equalization settings may be automatically determined (auto-calibration may be performed) for one channel at a time. However, it is possible to use regular data channels as feedback channels. In this case, tap coefficients may be simultaneously determined for more than one transmitting channel, e.g., multi-link auto-calibration may be performed.

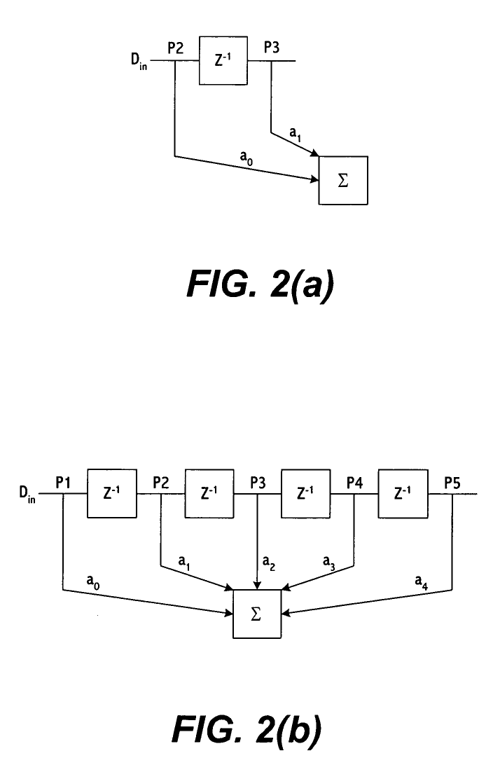

FIG. 2(a) shows a two-tap adaptive equalizer whose coefficients may be controlled in accordance with one or more embodiments of the present invention. The equalizer is shown as a time-varying (FIR) filter having an input Din which depends on the instantaneous state of the radio channel, one delay element Z⁻¹, two taps P2 and P3 and their corresponding coefficients a₀ and a₁, and a summer circuit 3 for generating a signal corresponding to an output of the equalizer. The tap coefficients are weight values which may be adjusted based on measured link loss in accordance with one or more embodiments of the present invention to achieve a specific level of performance, and preferably to optimize signal quality at the receiver.

FIG. 2(b) shows a five-tap adaptive equalizer having coefficients which may also be controlled in accordance with one or more embodiments described herein. This equalizer is shown as a time-varying (FIR) filter having an input Din which depends on the instantaneous state of the radio channel, four delay elements, and five taps P1 through P5 and their corresponding coefficients a₀ through a₄, and a summer 3 for generating a signal corresponding to an output of the equalizer. The tap coefficient are weight values which may be adjusted based on measured link loss in accordance with the embodiments of the present invention to achieve a specific level of performance, and preferably to optimize signal quality at the receiver.

A multi-tap equalizer as shown in FIG. 2(a) or 2(b) may be included in the transmitter, or at least at the transmitting side of the communication system, to perform loss-equalization correlation with a server channel or desktop channel. While two- and five-tap equalizers are shown for illustrative purposes, the transmitter may use an equalizer with any number of taps/tap coefficients that may be automatically calibrated as described herein.

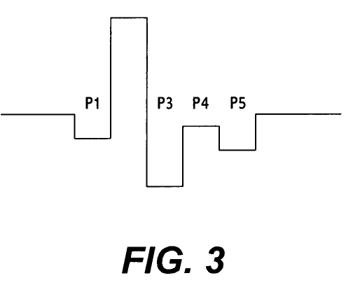

FIG. 3 shows an example of a lone pulse output from an equalizer which may be used for this purpose. In this diagram, P1, P3, P4, and P5 represent the pre-cursor, first post-cursor, second post-cursor, and third post-cursor magnitudes of the equalizer respectively. More specifically, P1 corresponds to the amplitude of the immediately preceding cursor before the main pulse. This is designed to cancel any “rise-time” delay induced ISI. P3 corresponds to the amplitude of the equalized cursor immediately after the main pulse. P4 corresponds to the amplitude of the equalized cursor immediately after P3. And, P5 corresponds to the amplitude of the equalized cursor immediately after P4. The values of P3-P5 are usually negative in order to negate the positive remnants of the main pulse beyond the bit-time. P2 stands for the amplitude of the main pulse (which is preferably normalized to a maximum V_{swing}) when sending a multi-tap equalized lone pulse. Also, fewer, more, or a different number of coefficients may be adjusted to achieve a specific level of performance.

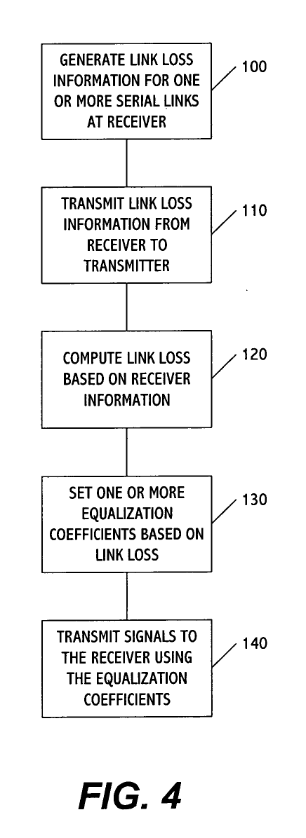

FIG. 4 shows functional blocks which may included in a method for automatically performing multi-tap equalization calibration in accordance with an embodiment of the present invention. Examples of circuits included in FIG. 1 which perform the functional blocks are discussed below.

During a link initialization procedure, the amount of loss is preferably determined for each link between the transmitter and receiver. (Block 100). This may be achieved in accordance with a handshaking and loop-back procedure performed between two chips which respectively include the transmitter and receiver. This procedure ensures that the chips are ready to participate in the equalization setting process. In calibrating each link/channel, different links may have different channel losses (different lengths, etc.). Accordingly, each channel may be calibrated individually.

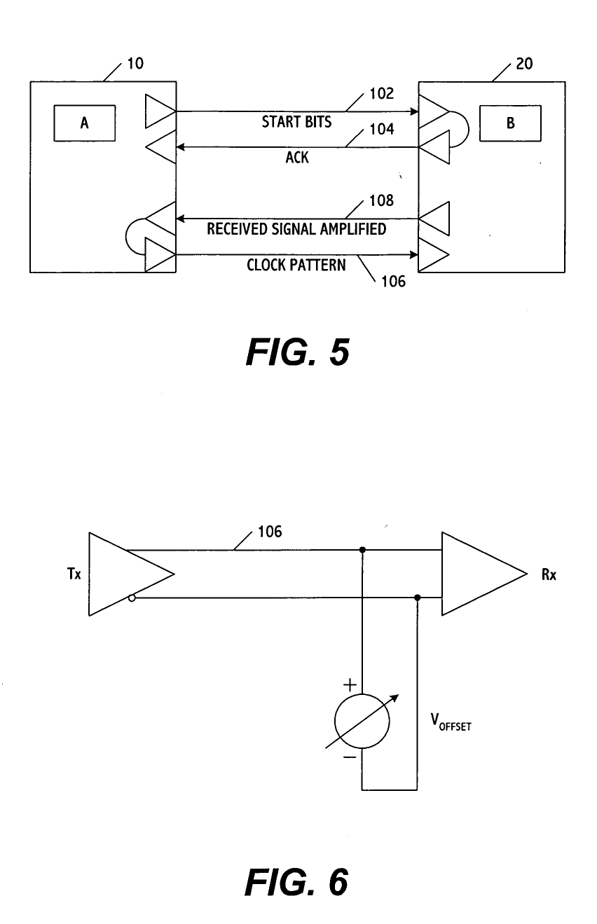

FIG. 5 shows the signal flow that may take place between two chips (e.g., integrated circuit chips illustratively labeled Chip A and Chip B, each of which preferably includes its own transmitter and receiver) during the handshaking and loop-back procedure. The chip which reaches a state for initiating the auto-equalization calibration procedure and then sends bits to start the procedure to the other chip is the first to go for auto-equalization. For example, if the transmitter of chip A reaches a state where auto-equalization calibration may be performed (e.g., at power-on/start-up, when catastrophic failures or link errors occur, or other times when the link needs to be re-trained), chip A transmits a signal containing one or more status bits to the receiver over a dedicated channel 102. The receiver of chip B then responds with an acknowledgment signal ACK over another dedicated channel 104, which may be referred to as a loop-back channel. Once the acknowledgment signal is received, a procedure for determining the loss in link 30 may be performed. Also, the status and acknowledgment signals may be transmitted bidirectionally over the same channel.

FIG. 6 shows a differential circuit that may be used in acquiring information that may be used in computing loss in link 30. This information is preferably acquired at the receiver and then fed back to the transmitter as follows.

Transmitter 10 sends a differential signal that includes a predetermined clock pattern to the receiver 20, whose input is offset calibrated (illustratively shown as an adjustable voltage source V_{offset}). The receiver sweeps the offset to determine the amplitude of the received signal preferably within one least significant bit (LSB) error. This amplitude measurement is preferably performed at a front-end sampling amplifier of the receiver. After the measurement is taken, the receiver sends a signal indicative of the received signal amplitude back to the transmitter, preferably along a dedicated channel.

Because the magnitude of the voltage offset calibration (VOC) can vary as a result of pressure, voltage, and temperature (PVT), dynamic adjustments may be performed to account for this variation. This may be accomplished using a DC pattern in a way which avoids non-linearity in voltage offset calibration ranges. For example, VOC may be performed by sending a clock pattern (e.g., a steady stream of DC “1” signals 106) from the transmitter to the receiver. The signal may be sent with a known (externally calibrated) swing, with the receiver termination open to ensure that no DC loss occurs. The receiver sweeps the offset and records the number of steps (NDC) required for determining the swing.

Determining this step count (N_{DC}) may be performed as follows. First, the offset is calibrated to record the zero position(s), i.e., the position at which the VOC offset is completely cancelled. This detection of zero position preferably occurs during initialization, when the VOC offset is swept by the offset canceller (e.g., it may be a block that is included in the sampling amplifier of FIG. 1). In order to count N_{DC}, the offset canceller increases the bit setting of the offset beyond the zero position count. At the instant when the sampling amplifier output changes sign, the bit setting is read and subtracted from the zero-position count. The number of steps of the bit setting that the offset canceller had to increase corresponds to N_{DC}. These steps may be counted by a counter present with the digital logic of the offset canceller.

Once step count N_{DC} has been determined, the receiver sends this information 108 back to the transmitter preferably at a reduced frequency using a loop-back channel. Once the transmitter side receives this information, the transmitter sends an acknowledgment (ACK) signal to the receiver, which then stops the transmission. (See FIGS. 5 and 6).

By virtue of design optimization, VOC is most linear around the common mode. For a single-ended swing of 500 mV, the common mode is about 250 mV. Usually, linearity is good for about 200 mV, i.e., 100 mV around the common mode. Therefore, for DC calibration to determine N_{DC}, a two-tap equalized DC signal may be used.

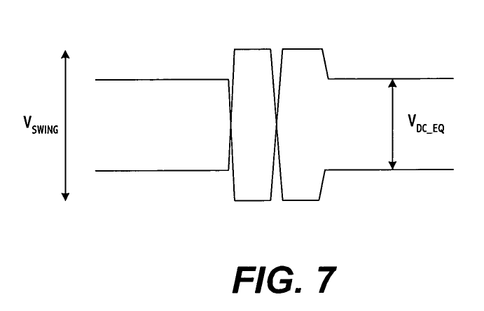

As shown in FIG. 7, when the signal swing V_{swing} is fixed and well determined (as it can be externally) over existing PVT conditions, the equalized DC voltage V_{dc}_{_{—}}_{eq} produced after application of a DC “1” pulse has little variation for a given two-tap equalization setting. The magnitude of V_{dc}_{_{—}}_{eq} has to be determined based on the linearity range of VOC. Generally, the larger V_{dc}_{_{—}}_{eq} is the better.

Once the transmitter sends the clock pattern signal at full swing to the receiver, the receiver again sweeps the offset and records the number of steps (N_{AC}) required for determining the clock amplitude of the signal. This clock amplitude is the amplitude of the clock signals, e.g., the amplitude of the 101010 . . . pattern that is being sent. The number of steps (N_{AC}) corresponds to the number of bit setting increases that the offset controller had to perform. This step count determination may be made in the same manner as discussed for N_{DC}, e.g., N_{AC} is the number of steps beyond the “zero position” of the VOC offset controller. The term “AC” in N_{AC} means an AC pattern, which, for example, may be 101010 . . . which is commonly referred to as a clock pattern in signaling terminology. (The actual clock amplitude of the 1011010 . . . pattern is not necessarily required because the system ultimately computes the ratio of N_{AC} to N_{DC}).

Information including N_{AC} is fed back from the receiver to the transmitter through the loop-back channel until an acknowledgment signal (ACK) is received from the transmitter. (Block 110). All exchanges of information between the transmitter and receiver over the link preferably occur at a frequency low enough that makes equalization of the information exchange unnecessary.

Notably, under conditions of reasonably close nearest lane-to-lane skew requirements, the information fed back between the transmitter and receiver may not even be necessary. For example, when the swing is constant and the same for both sides, the N_{AC} computed by the receiver of chip B (FIG. 3) may be used to calibrate the equalization of the transmitter-receiver links of chip B and vice-versa.

The transmitter computes loss in the link based on the information related to the link loss from the receiver. (Block 120). The loss may be computed, for example, as a ratio of the received transmitted clock pattern signal amplitudes. More specifically, the loss may be calculated based on a ratio of the number of VOC steps for DC and AC patterns (thereby eliminating PVT variation of step size in VOC), given by the following equation:
Loss(dB)=−20 log((N_{AC}/N_{DC})×(V_{dc}_{_{—}}_{eq}/V_{swing})) (1)

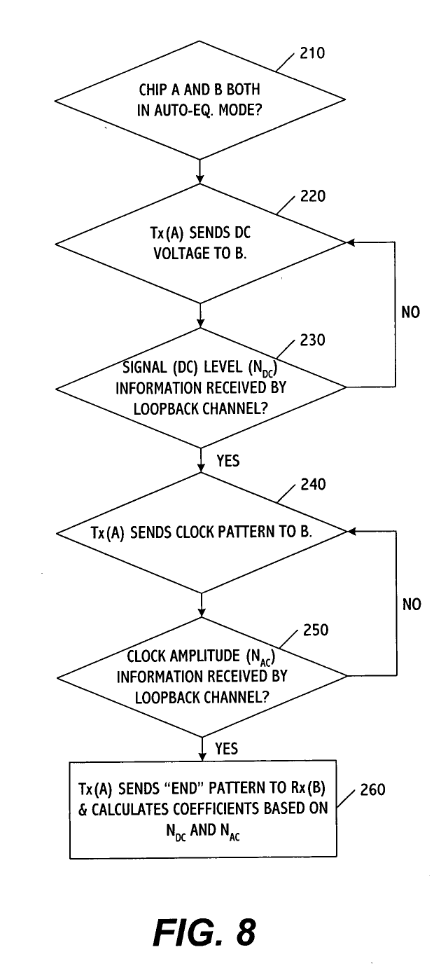

FIG. 8 is a flow chart summarizing blocks included in the method described up to this point. This procedure starts with the first bit of the chip (in this case Chip A) that reaches the auto-equalization state first and continues for all of its bits. Thereafter, Chip B reaches this state. (Block 210). The transmitter A then sends a DC voltage to the receiver B and the number of steps (N_{DC}) required for determining the voltage swing is computed. (Block 220). Next, a determination is made in the transmitter as to whether the signal (DC) level (N_{DC}) information has been received through the loop-back channel. (Block 230). If not, control returns to block 220. Otherwise, if N_{DC} has been received the transmitter sends a clock pattern to the receiver (Block 240). A determination is then made in the transmitter as to whether clock amplitude (N_{AC}) information has been received from the receiver through the loop-back channel. (Block 250). If not, control returns to Block 240. Otherwise, if N_{AC} has been received the transmitter sends an “end” pattern signal to the receiver, and calculates tap coefficients based on N_{AC} and N_{DC} using, for example, Equation (1). (Block 260).

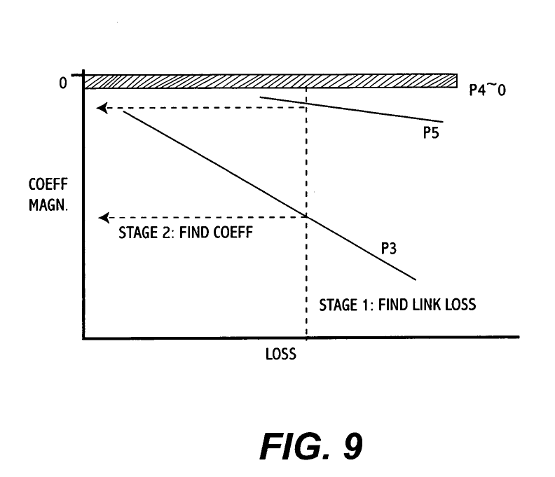

Returning to FIG. 4, the tap equalization coefficients are automatically determined based on the computed link loss to optimally match the link loss. (Block 130). This is may be accomplished by storing in advance one or more equalization coefficients for a corresponding number of link loss values. FIG. 9 is a graph which conceptually shows how this predetermined relationship may be formulated between two equalization coefficients and an range of link loss values. For illustration purposes, only the P3 and P5 coefficients are shown on the graph for multi-tap equalization, which, for example, may correspond to the five-tap equalizer shown in FIG. 2(b). Similar curves may be derived for remaining coefficients or one or more coefficients used for two-tap equalization.

To determine the values of the multi-tap coefficients, first, the computed link loss value is located on the horizontal axis. This value is then related to the P3 and P5 curves and their corresponding coefficients are determined on the vertical axis. These coefficients are preferably selected to reduce ISI distortion (e.g., to achieve optimal signal-to-noise ratio) in the associated channel. Optimal filter coefficients may, for example, correspond to those which maximize the voltage (and time) margins at the receiver. In other cases, non-optimal values may be used.

One way in which the equalization coefficients may be stored in advance is in the form of a look-up table. This table may be stored, for example, in a memory of the transmitter. Determining coefficients using the look-up table may be accomplished in various ways. For example, the look-up table may be searched to locate coefficients for two-tap based equalization. Alternatively, the look-up table may be searched to locate coefficients for multi-tap (e.g., more than two-tap) equalization, whichever is applicable to the given implementation.

In Equation (1), a division of N_{AC} and N_{DC} is performed to determine link loss (Loss dB). If the division cannot be simply performed, a user may insert a two-dimensional look-up table of N_{AC} and N_{DC} versus equalization settings. A look-up table of this type may be simplified and made smaller by tabulating only realistic ranges of N_{AC} and N_{DC}.

A variety of methods may be used to generate the equalization coefficients in the look-up table. As previously mentioned, these coefficients are preferably determined to maximize the received voltage, which may be accomplished by minimizing ISI distortion in the link. In other cases, the coefficients may be computed to achieve a different level of performance.

To determine the equalization coefficients stored in the look-up table, different combinations of links operating at the same loss may be chosen. Equalization coefficients for each link combination are then optimized using, for example, a peak-distortion analysis. In optimizing the coefficients, a predetermined standard may be observed, e.g., the coefficients must exist within a specific modeling error and one LSB. In one simulation, this was performed for two- and five-tap based equalization for three magnitudes of loss.

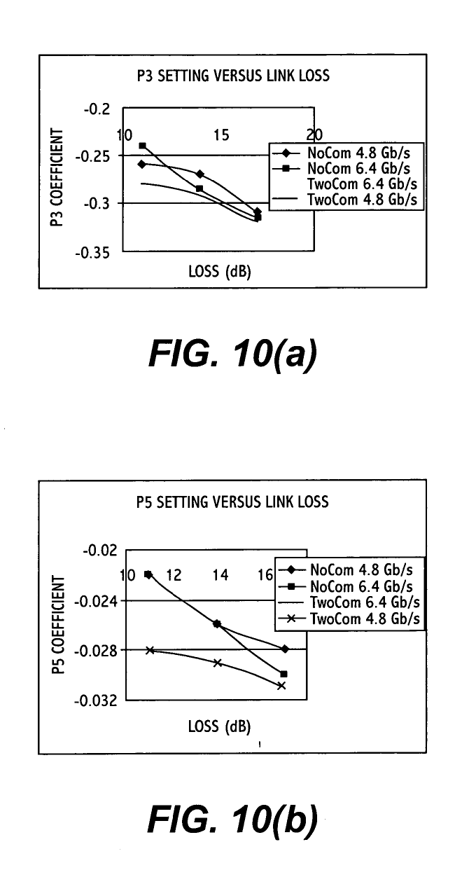

FIGS. 10(a) and 10(b) are graphs showing some of the coefficients obtained from a simulation performed for the five-tap equalization case. These coefficients may be included in a look-up table for use in optimally setting equalization in the transmitter in accordance with one or more of the embodiments described herein.

In FIG. 10(a), optimal values for the P3 coefficient were determined for three loss values (shown by the data points) under four different conditions. Curve 200 shows the P3 coefficients obtained for a data rate of 4.8 Gb/s for one board and no connector. Curve 210 shows the coefficients obtained for a data rate of 6.4 Gb/s for no connector. Curve 220 shows the coefficients obtained for a data rate of 6.4 Gb/s for 3 boards connected to each other using two connectors. And, curve 230 shows the coefficients obtained for a data rate of 4.8 Gb/s for 3 boards connected to each other using two connectors. This graph shows that under the exemplary set of conditions observed during the simulation, the optimum equalization settings for the dominant P3 term for the same loss are very similar to each other.

In FIG. 10(b), optimal values for the P5 coefficient were determined for three loss values (shown by the data points) under four different conditions. Curve 240 shows the P5 coefficients obtained for a data rate of 4.8 Gb/s for one board and no connector. Curve 250 shows the coefficients obtained for a data rate of 6.4 Gb/s for no connector. Curve 260 shows the coefficients obtained for a data rate of 6.4 Gb/s for 3 boards connected together using two connectors. And, curve 270 shows the coefficients obtained for a data rate of 4.8 Gb/s for 3 boards connected by two connectors. This graph shows that under the exemplary set of conditions observed during the simulation, the optimum equalization settings for the next dominant term P5 is not as close or sensitive as the values determined by the P3 term on a same-loss basis and that therefore the effect of P5 is not as strong.

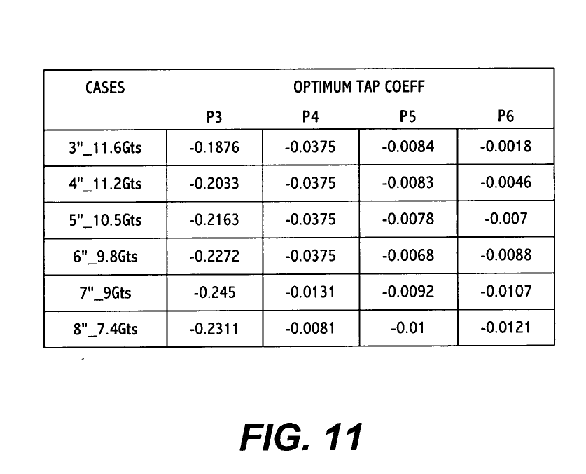

FIG. 11 is a chart showing an example of optimized coefficients determined for desktop channels for a single-board with no connector. As previously discussed, these coefficients may be determined in advance through empirical measurements/theoretical analysis such as a peak distortion analysis. In the chart, P3 through P6 coefficients are shown for six cases for the same loss (−12 dB). In each case, 3″ and 11.6 Gps, 4″ and 11.2 Gps, 5″ and 10.5 Gps, 6″ and 9.8 Gps, 7− and 9 Gps, and 8″ and 7.4 Gps. The chart values show the optimized eye dimensions obtained when the equalization coefficients are optimized for each case versus when the equalization coefficients are optimized for one case (the 5″ case) and applied to all other cases. The degradation in the eye size is minimal (e.g., within 3 to 4%). Also, the lengths given in inches do not include package traces, but only the total board length without connectors.

After the equalization coefficients have been determined, the transmitter adjusts its equalization registers (e.g., FIR filters) and begins sending patterns at the equalized settings. These patterns may include actual data, the nature of which may be unknown and unpredictable. For example, the patterns may include any sequence of 1's and 0's and hence maybe regarded as random data (as opposed to the calibration interval, where deterministic patterns such as DC=1 or . . . 10100 . . . are sent out).

An optional stage involves fine tuning the setting by measuring the voltage and timing margins of the eye at the receiver pad. An on-die method of determining the “eye” seen at the pad is one method that may be used for fine-tuning. In this method, the sampling clocks out of the interpolator are made to sweep over various bit settings and the settings at which a failure occurs to detect the data correctly are noted. A measure of the extent of the timing margin is obtained as a result.

The VOC offset is then made to sweep over various settings to determine the extent of the voltage margin using a similar algorithm. This method of determining the timing and voltage margin is repeated in an automated fashion over two or three equalization settings to determine which setting is the most optimum point, thereby determining an optimum equalization setting. It is expected that this method of fine tuning will provide about 3-8% increase in eye.

Optionally, the loss information can be used to select the filter taps and coefficients to adjust terminations and transmitter drive settings. A tradeoff may exist, however, between eye size and power dissipation

By performing a non-iterative one-shot determination of the equalization settings, one or more of the embodiments described herein significantly shorten the amount of time for determining the optimal equalization settings at the receiver. This may only require a few thousand UI or about nsec and no extra hardware compared to other approaches which have been taken for determining equalization settings.

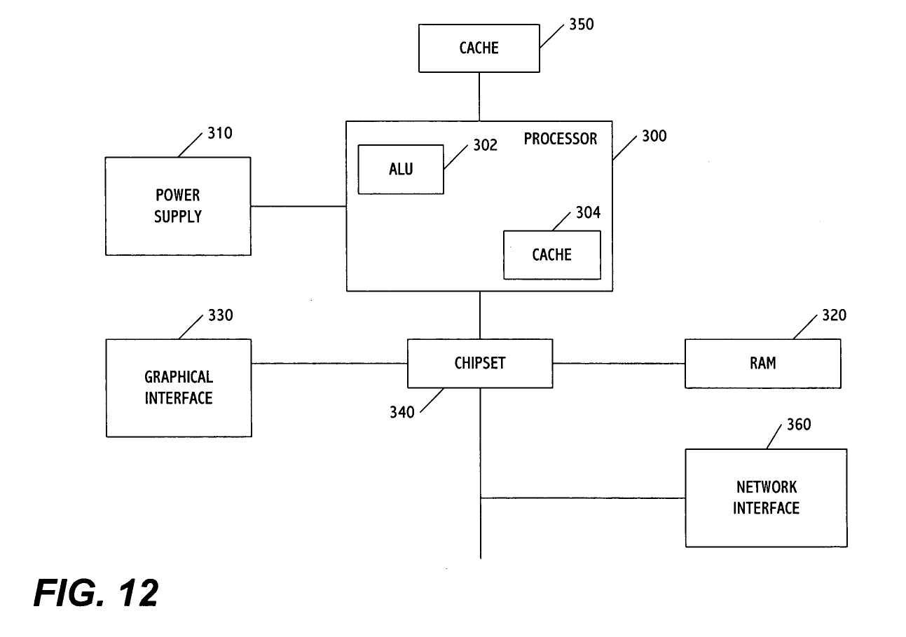

FIG. 12 shows a processing system which includes a processor 300, a power supply 310, and a memory 320 which, for example, may be a random-access memory. The processor includes an arithmetic logic unit 302 and an internal cache 304. The system also preferably includes a graphical interface 430, a chipset 340, a cache 350, and a network interface 360. The processor may be a microprocessor or any other type of processor. If the processor is a microprocessor, it may be included on a chip die with all or any combination of the remaining features, or one or more of the remaining features may be electrically coupled to the microprocessor die through known connections and interfaces. The embodiments of the present invention described herein may be implemented between a CPU and Chipset connection, between a Chipset and RAM connection, and between a cache and CPU connection. An implementation between the graphical interface and one or more of the CPU, chipset, and RAM is also possible. In any of these implementations or embodiments described herein, an adaptive process may be used during an initialization stage to set the transmitter multi-tap equalizer coefficients for any individual lane.

In addition to spread-spectrum systems, the embodiments of the present invention described herein may also be used in other types of communication systems including but not limited to ones utilizing copper inter-connects (SMA cables, printed circuit boards using FR-4 etc.).

In accordance with another embodiment of the present invention, a computer-readable medium storing a program which includes code sections for performing all or a portion of the functional blocks of the methods described herein. The computer-readable medium may be an integrated circuit memory formed on a same chip as and electrically coupled to the equalizer, or the medium may be another type of storage medium or device. A controller such as a CPU or other processor circuit may be used to execute the program for searching the look-up table and adjusting the equalization settings based on the search results as previously described.

In any of the aforementioned embodiments, the equalizer may perform the search of the look-up table or the search may be performed by a controller or processing circuit that is either resident on the board or chip containing the equalizer or off-board or off-chip.

Any reference in this specification to an “embodiment” means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Furthermore, for ease of understanding, certain functional blocks may have been delineated as separate blocks; however, these separately delineated blocks should not necessarily be construed as being in the order in which they are discussed or otherwise presented herein. For example, some blocks may be able to be performed in an alternative ordering, simultaneously, etc.

Although the present invention has been described herein with reference to a number of illustrative embodiments, it should be understood that numerous other modifications and embodiments can be devised by those skilled in the art that will fall within the spirit and scope of the principles of this invention. More particularly, reasonable variations and modifications are possible in the component parts and/or arrangements of the subject combination arrangement within the scope of the foregoing disclosure, the drawings and the appended claims without departing from the spirit of the embodiments of the invention. In addition to variations and modifications in the component parts and/or arrangements, alternative uses will also be apparent.

1. A board, comprising:
a transmitter; and
an equalizer to automatically determine a multi-tap equalization setting based on loss of a link coupled to the transmitter.

2. The board of claim 1, wherein the equalization setting is a two-tap equalization setting.

3. The board of claim 1, wherein the equalization setting is a five-tap equalization setting.

4. The board of claim 1, further comprising:
receiving a signal which includes link loss information through a predetermined channel.

5. The board of claim 1, further comprising:
a look-up table to store a plurality of tap coefficient settings in correspondence with a respective number of link loss values, the equalizer searching the look-up table for a tap coefficient setting which corresponds to the link loss.

6. The board of claim 1, wherein the equalizer determines the equalization setting during link initialization.

7. The board of claim 1, wherein the equalizer receives information indicative of voltage and timing margins of an eye diagram at a receiver and adjusts the equalization setting based on the voltage and timing margins.

8. A method, comprising:
measuring loss in a link between a transmitter and a receiver; and
automatically determining a multi-tap equalization setting for the transmitter based on the measured loss.

9. The method of claim 8, wherein the equalization setting is a two-tap coefficient setting.

10. The method of claim 9, wherein the equalization setting is a five-tap coefficient setting.

11. The method of claim 8, wherein measuring the loss is performed at the receiver.

12. The method of claim 11, wherein measuring the loss includes:
transmitting a clock signal from the transmitter to the receiver; and
computing the loss as a ratio of the transmitted clock signal amplitude and the received clock signal amplitude.

13. The method of claim 12, wherein the receiver receives the clock signal through an input which is offset calibrated.

14. The method of claim 13, wherein the receiver sweeps the offset to determine the amplitude of the received clock signal to within a predetermined error.

15. The method of claim 14, wherein the predetermined error is one LSB error.

16. The method of claim 14, wherein the loss is measured based on the following equation:
Loss(dB)=−20 log(N_{AC}/N_{DC})*(V_{dc}_{_{—eq}}/V_{swing})
where N_{AC} is a number of steps to determine the amplitude of the received clock signal, N_{DC} is a number of steps to determine a voltage swing of a DC voltage transmitted to the receiver, V_{dc}_{_{—}}_{eq} is an equalized DC voltage, and V_{swing} is the voltage swing.

17. The method of claim 8, further comprising:
storing a look-up table that includes a plurality of tap coefficient settings in correspondence with a respective number of loss values, wherein determining the equalization setting includes searching the look-up table for a tap coefficient setting which corresponds to the measured loss and setting an equalizer in the transmitter based on the tap coefficient setting obtained from the search.

18. The method of claim 17, wherein measuring the loss and determining the multi-tap equalization setting are performed during link initialization.

19. The method of claim 8, further comprising:
measuring voltage and timing margins of an eye diagram at the receiver; and
tuning the multi-tap equalization setting based on the voltage and timing margins.

20. A system, comprising:
a first circuit;
a second circuit; and
a data link connecting the first and second circuits, wherein at least one of the first and second circuits includes:
(a) a transmitter, and
(b) an equalizer to automatically determine a multi-tap equalization setting based on a measured loss of the data link.

21. The system of claim 20, wherein the first circuit includes a chipset and the second circuit includes a CPU.

22. The system of claim 20, wherein the first circuit includes a chipset and the second circuit includes a memory.

23. The system of claim 20, wherein the memory is one of a RAM and a cache.

24. The system of claim 20, wherein the first circuit includes a memory and the second circuit includes a CPU.

25. The system of claim 20, wherein the first circuit includes a graphical interface and the second circuit includes at least one of a memory, CPU, and chipset.

26. The system of claim 20, wherein said at least one of the first and second circuits include:
a look-up table to store a plurality of tap coefficient settings in correspondence with a respective number of link loss values, the equalizer searching the look-up table for a tap coefficient setting which correspond to the link loss.

27. The system of claim 20, wherein the equalizer determines the equalization setting during link initialization.

28. A computer-readable medium storing a program to control equalization in a board, said program including:
a first code section to search a look-up table based on loss of a link connected to the board, said table storing a plurality of tap coefficient settings in correspondence with a respective number of loss values; and
a second code section to adjust an equalizer based on a tap coefficient setting generated from the search.

29. The computer-readable medium of claim 28, wherein the second code section adjusts the equalizer based on the tap coefficient setting during link initialization.

30. The computer-readable of claim 28, further comprising:
a third code section which tunes the equalization setting based on voltage and timing margins of a receiver eye diagram.
